(19) United States
(12) Patent Application Publication
(10) Pub. No.: US 2008/0296756 A1
(43) Pub. Date: Dec. 4, 2008

(54) HEAT SPREADER COMPOSITIONS AND MATERIALS, INTEGRATED CIRCUITRY, METHODS OF PRODUCTION AND USES THEREOF

(76) Inventors: James L. Koch, Newman Lake, WA (US); Brian D. Ruchert, Newman Lake, WA (US); James P. Flint, Mead, WA (US); Patrick K. Underwood, Spokane, WA (US)

Correspondence Address: BUCHALTER NEMER, 18400 VON KARMAN AVE., SUITE 800, IRVINE, CA, 92612, US

(21) Appl. No.: 11/755,610

(22) Filed: May 30, 2007

(51) Int. Cl. H01L 23/34; H05K 7/20

(52) U.S. Cl. 257/713; 361/718; 257/E23.08

(57) ABSTRACT

Near net shape heat spreader components are disclosed that comprise at least one pressure-treated powder material. Heat spreaders are also described that include at least one near net shape heat spreader component, and at least one additional part. Methods of forming heat spreaders are also described that include: a) forming a base portion comprising a pressure-treated powder material and having a first surface comprising a perimeter region surrounding a heat-receiving surface; b) forming a frame portion comprising a second material; and c) joining the base portion and the frame portion.

### FIELD OF THE SUBJECT MATTER

The field is related to heat spreader constructions, methods of forming heat spreaders, integrated circuitry incorporating heat spreaders, methodology for forming such integrated circuitry and uses of the materials, compositions and devices described herein.

### BACKGROUND

Electronic components are used in ever increasing numbers in consumer and commercial electronic products. Examples of some of these consumer and commercial products are televisions fiat panel displays, personal computers, gaming systems, Internet servers, cell phones, pagers, palm-type organizers, portable radios, car stereos, or remote controls. As the demand for these consumer and commercial electronics increases, there is also a demand for those same products to become smaller, more functional, and more portable for consumers and businesses.

As a result of the size decrease in these products, the components that comprise the products must also become smaller. Examples of some of those components that need to be reduced in size or scaled down are printed circuit or wiring boards, resistors, wiring, keyboards, touch pads, and chip packaging. Products and components also need to be prepackaged, such that the product and/or component can perform several related or unrelated functions and tasks. Examples of some of these “total solution” components and products comprise layered materials, mother boards cellular and wireless phones and telecommunications devices and other components and products, such as those found in U.S. Patent and PCT Application Ser. Nos. 60/396294 filed Jul. 15, 2002, 60/294433 filed May 30, 2001, Ser. No. 10/519337 filed Dec. 22, 2004, Ser. No. 10/551305 filed Sep. 28, 2005, Ser. No. 10/465968 filed Jun. 26, 2003 and PCT/US02/17331 filed May 30, 2002, which are all commonly owned and incorporated herein in their entirety.

Components, therefore, are being broken down and investigated to determine if there are better building materials and methods that will allow them to be scaled down and/or combined to accommodate the demands for smaller electronic components. In layered components, one goal appears to be decreasing the number of the layers while at the same time increasing the functionality and durability of the remaining layers and surface/support materials. This task can be difficult, however, given that several of the layers and components of the layers should generally be present in order to operate the device.

Also, as electronic devices become smaller and operate at higher speeds, energy emitted in the form of heat increases dramatically with heat flux often exceeding 100 W/cm². Thermal management in electronic devices is important for proper device performance. Thermal management components such as heat sinks and heat spreaders are utilized to decrease potential negative impacts of heat-generating components in a wide range of electronic devices by aiding in the transfer of heat to the ambient environment.

One area of particular importance for developing thermal management technology is integrated circuitry. With advances in device and integrated circuit (IC) technology, faster and more powerful devices are being developed. Faster switching and an increase in transistors per unit area in turn lead to increased heat generation. Packaging for these devices can typically incorporate a heat spreader which assists in heat transfer from the devices cc to a heat sink. Heat dissipation from the devices can have a large role in device stability and reliability.

Thermal management and removal of heat can be particularly important and challenging in the area of flip-chip technology which is utilized for connecting high performance integrated circuit devices to substrates. Heat spreaders can typically be utilized in flip-chip technology to provide a lower thermal resistance pathway between the chip and ultimate heat sink. Various materials such as copper and aluminum alloys have been utilized for flip-chip heat spreader applications. In particular instances, materials such as carbon-carbon composites or diamond can be advantageously utilized for heat spreader applications due to their exceptional thermal conductivity. Diamond and carbon-carbon composite heat spreaders can have greatly enhanced thermal transfer rates relative to alternative materials having lower thermal conductivity. Diamond heat spreaders can also allow a better thermal expansion match between the chip and packaging components. However, due to the expense of diamond materials and the relative difficulty in fabricating conventional heat spreader configurations utilizing diamond or composite carbon-carbon materials heat spreaders for flip-chip and other microelectronic applications fabricated from these materials can be cost prohibitive.

Thus, there is a continuing need to: a) design and produce thermal interconnects and thermal interface materials, layered materials, components and products that meet customer specifications while minimizing the size of the device and number of layers; b) produce more efficient and better designed materials, products and/or components with respect to the compatibility requirements of the material, component or finished product; c) produce materials and layers that are more compatible with other layers, surfaces and support materials at the interface of those materials; d) develop reliable methods of producing desired thermal interconnect materials, thermal interface materials and layered materials and components/products comprising contemplated thermal interface and layered materials; e) develop materials that possess a high thermal conductivity and a high mechanical compliance; f) effectively reduce the number of production steps necessary for a package assembly, which in turn results in a lower cost of ownership over other conventional layered materials and processes; and g) effectively reduce cost of manufacture of the thermal transfer components.

### SUMMARY OF THE SUBJECT MATTER

Near net shape heat spreader components are disclosed that comprise at least one pressure-treated powder material. Heat spreaders are also described that include at least one near net shape heat spreader component, and at least one additional part.

Methods of forming heat spreaders are also described that include: a) forming a base portion comprising a pressure-treated powder material and having a first surface comprising a perimeter region surrounding a heat-receiving surface; b) forming a frame portion comprising a second material; and c) joining the base portion and the frame portion.

### BRIEF DESCRIPTION OF THE FIGURES

Prior Art FIG. 1 is an isometric view of a heat spreader configuration.

FIG. 2 is an isometric view of a heat spreader configuration,

FIG. 3 is an exploded isometric view of the heat spreader configuration shown in FIG. 2.

FIG. 4 is an alternate isometric view of the heat spreader configuration shown in FIG. 2,

FIG. 5 is a cross-sectional side view taken along line 5-5 of FIG. 4.

FIG. 6 is a side view of a contemplated heat spreader plate.

FIG. 7 is a side view of an assembled heat spreader containing the heat spreader plate shown in FIG. 6.

FIG. 8 is a cross-sectional fragmentary view of integrated circuitry.

### DETAILED DESCRIPTION

Thermal management for flip-chip and other microelectronic devices can affect device lifetime and performance. Improved methods and configurations for heat transfer away from such microelectronic devices can play an important role in allowing development of faster and more powerful devices. Accordingly, new configurations for diamond, carbon composite and alternative thermal control material heat spreaders are desired for flip-chip technology and other integrated circuitry as well as other electronic device applications.

Surprisingly, thermal interface and heat spreader materials, and their methods of production, have been developed that: a) meet customer specifications while minimizing the size of the device and number of layers; b) are more efficient and better designed materials, products and/or components with respect to the compatibility requirements of the material, component or finished product; c) are more compatible with other layers, surfaces and support materials at the interface of those materials; d) are produced reliably; e) possess a high thermal conductivity and a high mechanical compliance; f) effectively reduce the number of production steps necessary for a package assembly, which in turn results in a lower cost of ownership over other conventional layered materials and processes; and g) effectively reduce cost of manufacture of the thermal transfer components. Some heat spreader configurations contemplated allow materials with high heat conductivity to be localized in appropriate heat-receiving/dissipating areas while replacing less critical regions of the spreader with less expensive and/or more easily fabricated materials.

Heat spreaders, such as the one shown in FIG. 1, are coupled with flip-chips for the purpose of distributing and diffusing heat from other surrounding components or layers. Heat spreaders can be formed from any of a variety of known materials, including copper, copper alloys, diamond aluminum, aluminum alloys, carbon-carbon composite materials, copper composites, aluminum silicon carbide, copper-tungsten, copper-molybdenum copper, silicon carbide, diamond composite materials or combinations thereof. Some of these materials have limited ductility and when they are utilized for forming heat spreaders, certain processes may not be feasible, such as stamping, coining or other plastic deformation methods. Where the material utilized is expensive, such as for example, diamond, the cost of forming openings in some heat spreaders and the additional waste of material which is removed to form such opening can be cost prohibitive. Since conventional methods cannot be utilized to form heat spreader components comprising those materials disclosed above, other methods and modified materials need to be developed to formulate heat spreader components.

In response to the goals and needs previously disclosed, near net shape inserts and other components for a heat spreader has been developed and is described herein. In addition, heat spreaders comprising these near net shape inserts and other components have also been developed and are described. Methods of forming the near net shape inserts, the near net shape other components and the heat spreaders comprising these inserts and other components are described. As used herein, the phrase “near net shape” refers to an industrial production technique whereby the initial production of a component is very close to its final (net) shape. By producing near net shape components, the finishing time and processing steps are greatly reduced as compared to traditional components.

Near net shape components, including inserts, heat spreader lids, heat spreader frames, heat spreader supports or a combination thereof, comprise a pressure-treated powder material. These components can be incorporated with conventional heat spreader frames and supports to form a heat spreader. These components can also be coupled with heat spreader frames and supports made from the same pressure-treated powder material. Methods of producing near net shape components comprise: a) providing a powder material and b) pressure-treating the powder material such that a near net shape component is formed.

Contemplated powder materials comprise those powders and materials which are suitable in a heat spreader application and can form high density, low coefficient of thermal expansion materials after being pressure-treated. These materials and powders can be those mentioned earlier, including copper, copper alloys diamond, aluminum, aluminum alloys, carbon-carbon composite materials, copper composites, aluminum silicon carbide, copper-tungsten, copper-molybdenum copper, silicon carbide, copper silicon carbides, copper diamond powders, diamond composite materials or combinations thereof.

These materials can be pressure-treated by any suitable pressure-treating method or device, including hot isostatic pressure, hot pressing, press forming or a combination thereof. These methods are similar to those used in the sputtering target manufacturing. It is contemplated that the pressure-treating will form a high density, low coefficient of thermal expansion material having a high thermal conductivity material. In some embodiments, a suitable low coefficient of thermal expansion is less than about 25 ppm/K. In other embodiments, a contemplated low coefficient of thermal expansion is less than about 20 ppm/K. In yet other embodiments, a contemplated low coefficient of thermal expansion is less than about 14 ppm/K. In some embodiments, a suitable low coefficient of thermal expansion is less than about 12 ppm/K. In yet other embodiments, a suitable low coefficient of thermal expansion is less than about 10 ppm/K. In some embodiments, a suitable high thermal conductivity material comprises a conductivity of at least about 350 W/m-K. In other embodiments, a suitable high thermal conductivity material comprises a conductivity of at least about 400 W/m-K. In yet other embodiments, a suitable high thermal conductivity material comprises a conductivity of at least about 500 W/m-K. In yet embodiment, a suitable high thermal conductivity material comprises a conductivity of at least about 600 W/m-K.

In addition, another thermally conductive material may be pressure-treated along with the powder material, in order to form a modified near net shape component. For example, a layer or web-type material comprising thermally conductive fibers, nanotubes, particles, flakes or combinations thereof may be coupled with the powder material prior to pressure-treating in order to form one component post-treatment. These additional materials may comprise any suitable thermally conductive material, such as carbon crosslinked polymers metals and alloys or combinations thereof. This additional material may also aid in adhesion with other layers in the final component.

Once the contemplated near net shape components are formed, they can be utilized to form all or part of a heat spreader. When the phrase “all or part of a heat spreader” is used, it is important to understand the different types of heat spreaders and how they are constructed. A conventional heat spreader, as shown in FIG. 1, is a ‘lid” type heat spreader 10 that comprises a single piece of material. This single piece heat spreader can typically be fabricated by, for example, stamping, coining and/or machining from a single sheet of material. In this particular example, heat spreader 10 can have an opening, cavity or recess 12 having a base surface 14 and can have an opposing back surface 16. Base surface 14 can function as a heat-receiving surface relative to a surface of the flip-chip and thereby allow heat dissipation from the flip-chip through spreader 10. Conventional heat spreader 10 can be disposed over a microelectronic device and an upper surface 18 can interface an integrated circuitry board, or package substrate (not shown). In particular applications, opposing face 16 can be disposed interfacing an appropriate heat sink (not shown).

Because of the single piece configuration of heat spreader 10, fabrication of the heat spreader and formation of form cavity 12 can be time consuming, difficult and/or expensive based upon the particular material utilized. Where recess 12 is formed by machining out an opening within a material, such can result in waste of the material from such machined out portion. Materials and methods described herein that utilize pressure-treated powder materials can more easily form these types of single piece configurations, because they initially form the spreader as a near net shape spreader with the appropriate mold, cast, shapes, dies or combinations thereof.

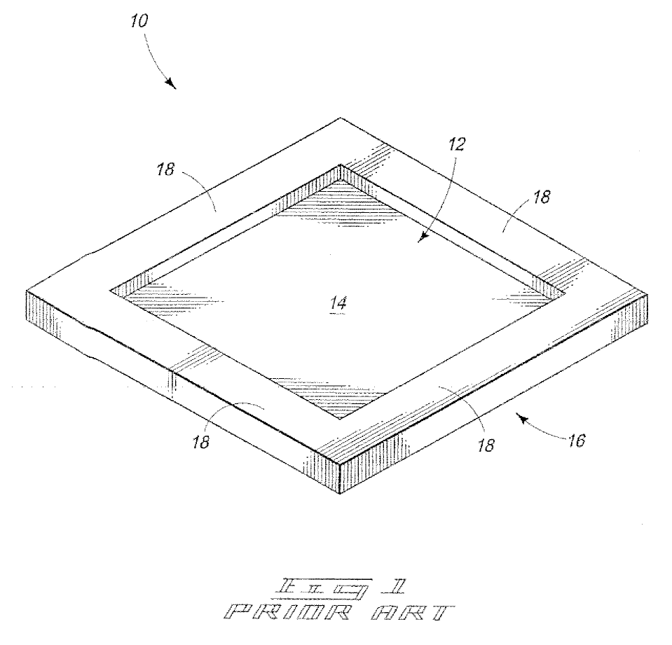

There are additional types of heat spreaders other than the conventional one described above For example, U.S. patent application Ser. No. 10/585275 discloses a multi-part heat spreader component. This patent application is commonly-owned and incorporated into this document by reference in its entirety. These types of heat spreader configurations are shown in FIGS. 2-5. FIG. 2 shows a heat spreader 10 having a first portion or ‘base’ potion 20 and a second independently formed raised ‘frame’ portion 30 Heat spreader 10 can have a heat-spreading surface 22 which can ultimately be disposed interfacing a “hot device” surface, where the term “hot device” refers to a heat-generating device from which heat is to be drawn away.

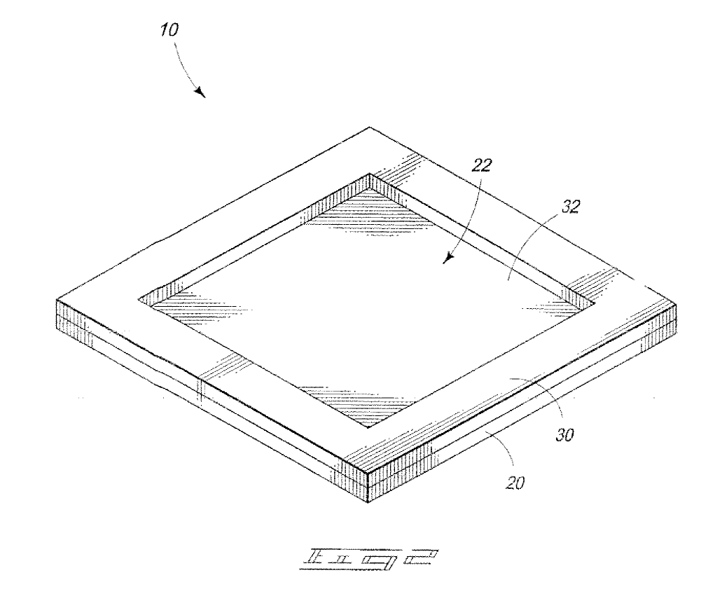

FIG. 3 shows an exploded view depicting the two separate pieces 20 and 30 which can together form spreader 10. As shown, surface 22 of base piece 20 can have an interior region 23 which can be referred to as a heat-receiving surface, at least a portion of which will interface a hot device. Base piece 20 also has a perimeter region 24 of surface 22 which interfaces independent frame piece 30.

Frame portion 30 of heat spreader 10 can be described as having a first interface surface 34 which wit I be disposed interfacing the base portion, and a second opposing interface surface 36 which can interface, for example a circuit board. When the two pieces 20 and 30 are joined as shown in FIG. 2, piece 30 can frame heat-receiving surface 23 within an opening 32 which transverses frame piece 30.

Base piece 20 can comprise any suitable heat spreading material, such as those materials described herein that utilize pressure-treated powder materials. In some embodiments, materials which may be used to make the base piece 20 comprise copper, copper alloys (e.g., Cu—Ni), aluminum, aluminum alloys, composite carbon-carbon materials, SiC, graphite, carbon, diamond and diamond composites (i.e. diamond composites comprising SiC, graphite or carbon) and combinations thereof. It is contemplated that base piece 20 can have thermal expansion coefficients, such as those already mentioned. It is also contemplated that the thermal expansion coefficient is less than about 9 ppm/K, and in some applications can have a coefficient of thermal expansion of less than about 6 ppm/K.

Base portion 20 and frame portion 30 can be formed of the same material or can have differing compositions relative to one another. Because base portion 20 is the primary dissipating region of the heat spreader, second portion 30 can in particular applications comprise a less expensive mat rial, a more easily fabricated material and/or a material with a lower thermal conductivity relative to base portion 20. Accordingly, the cost of materials for the two piece heat spreader in accordance with the invention can be significantly less than conventional single piece heat spreader configurations.

Frame portion 30 can be formed by, for example, stamping, coining and/or machining. Frame portion 30 can be manufactured from any suitable material, including copper, copper alloys, carbon composite, aluminum, aluminum alloys, diamond, ceramic, molybdenum, tungsten, KOVAR® (Westinghouse Electric and Manufacturing Company, Pittsburgh Pa.), alloy 42, SiC, carbon, graphite, diamond composites (see above, for example), and combinations thereof. Alternatively or in addition to these materials, frame portion 30 can comprise an appropriate heat-stable polymer material.

Although parts 20 and 30 are shown having approximately equal thickness, it is contemplated that they may individually be any relative thicknesses. The thickness of part 30 can depend upon the thickness of an interfacing hot device, frame part 30 can preferably have a thickness which allows clearance of surface 22 when spreader 10 is disposed over and in heat-receiving relation relative to a device with frame surface 36 interfacing a circuit board (discussed below). The thickness of base portion 20 can depend on a number of factors including, the amount of heat generated by the hot device, the heat spreading material(s) utilized and the coefficients of thermal expansion of such material(s).

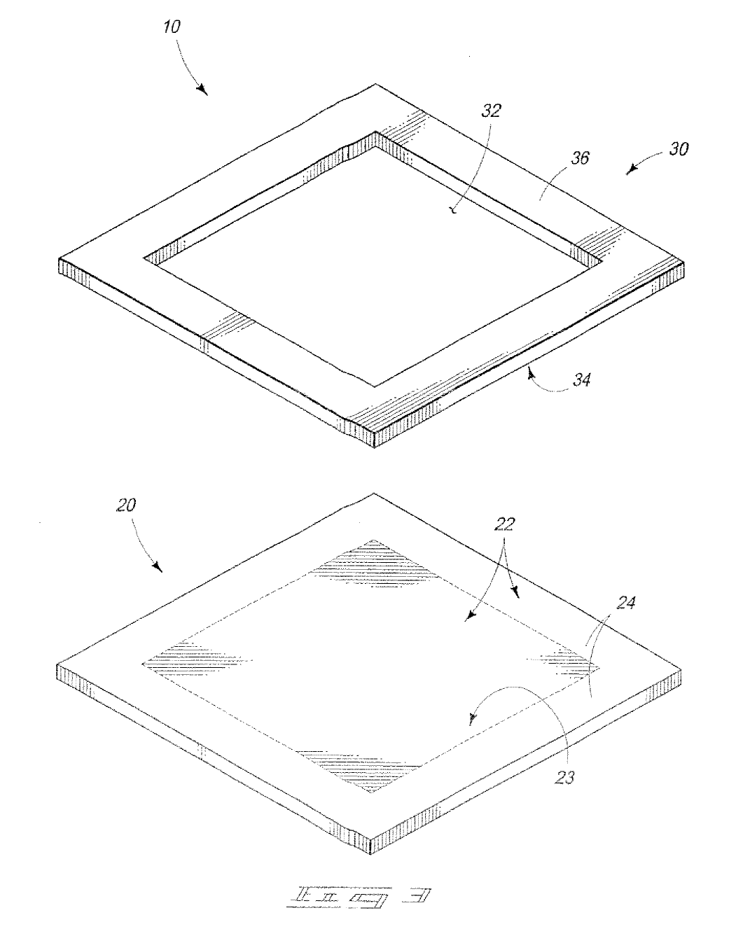

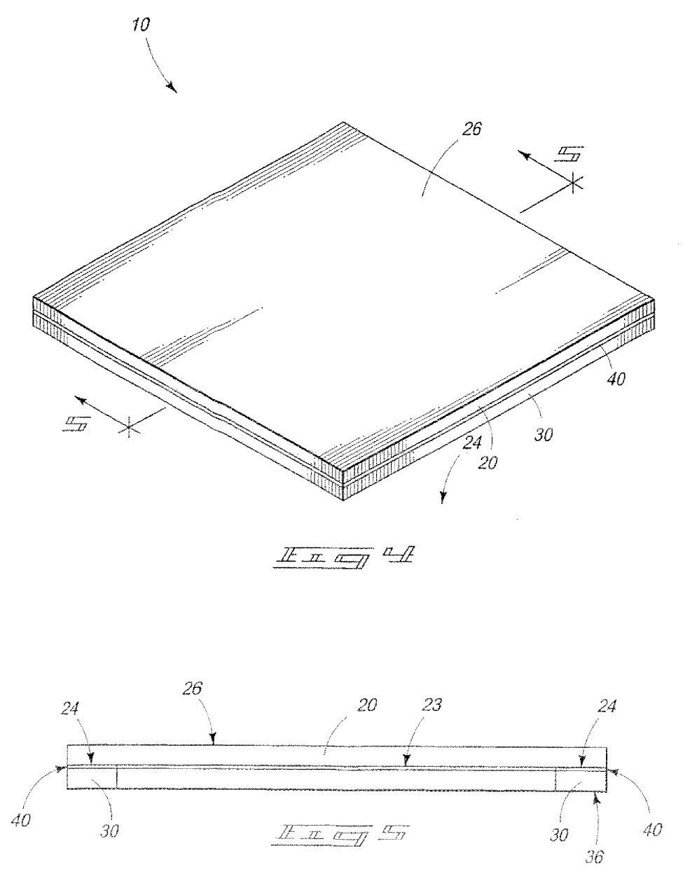

FIG. 4 shows an alternative view of heat spreader 10 rotated 180° relative to the view shown in FIG. 2. As shown in FIG. 4, a backside 26 of base piece 20 can oppose heat spreading surface 22 (FIG. 2). As additionally shown in FIG. 4, base part 20 can be joined to frame portion 30 by an interface material 40 disposed between the interfacing surfaces of the two pieces material 40 can be, for example, an adhesive or solder. Alternatively, pieces 20 and 30 can be joined in an absence of interfacing material by, for example, diffusion bonding or other direct bonding techniques.

FIG. 5 shows a cross-section of the two part heat spreader taken along line 5-5 of FIG. 4. As shown in FIG. 5, interface material 40 can be disposed between the perimeter region 24 of base portion 20 and interfacing surface 34 of frame portion 30. In particular applications, base piece 20 can comprise a heat spreader material 27 which can be any of the materials discussed above with respect to base piece 20, and can additionally comprise a coating material 28. Coating material 28 can cover an entirety of surface 22. Alternatively, material 28 can cover one or more portions of surface 22 such as, for example, perimeter surfaces 24 (shown in FIG. 3) which will interface frame portion 30.

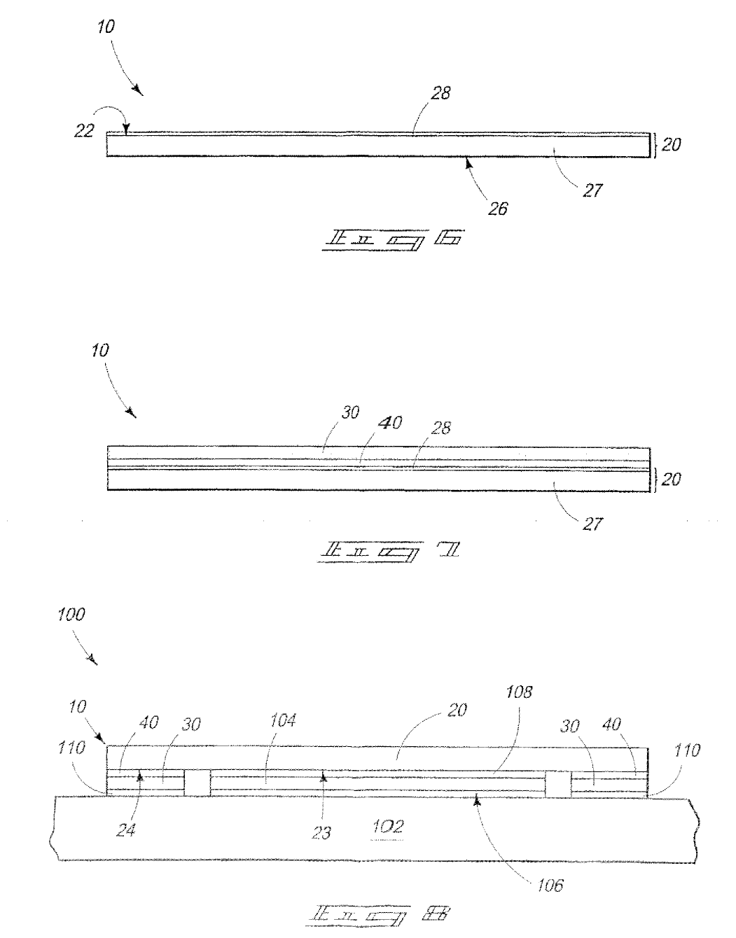

FIG. 7 shows assembled two-piece heat spreader 10 having coating material 28 disposed between interlace material 40 and heat spreader material 27. Coating material 28 can comprise, for example, a metal or metallic material. In applications where heat spreader material 27 is difficult to solder (e.g., diamond) coating material 28 can be a metallized layer deposited over the diamond to allow base portion 20 to be soldered to frame portion 30. In one embodiment base portion 20 can comprise a diamond material 27 and a metallized coating 28 which can be, for example, gold. Interface material 40 can be a solder material which bonds to metallized layer 28 and frame portion 30.

Referring again to FIG. 4, heat spreader 10 can be substantially square as depicted. It is to be understood, however, that the invention encompasses alternative heat spreader shapes such as, for example, circular, rectangular, etc., including irregular shapes. Base portion 20 and frame portion 30 can be fabricated accordingly. The shape of heat spreader 10 can of course depend upon the shape of an underlying heat-generating device.

In addition to the single piece base portion shown in the Figures, a plurality of pieces may also be used to form base plate 20 (not shown). Where multiple pars form base plate 20, the pans can comprise the same material or different materials, For example, a material such as diamond can be localized to a portion of plate 20 which will interface a ‘hot spot’ or a particularly hot portion of a device, while surrounding parts or parts of plate 20 more remote from the hot spot are formed from a less expensive material and/or a material with a lower coefficient of thermal expansion.

Frame pan 30 can also comprise multiple pieces and/or multiple materials (not shown). Additionally, frame part 30 can be discontinuous, covering only a portion of perimeter region 24 of base plate 20. For example, frame part 30 can be fragments or spaced blocks along perimeter region 24 sufficient to provide clearance and support for base plate 20 when disposed over a heat-generating device.

It is to be additionally noted that although this particular heat spreader is discussed as having a single recessed compartment (i.e. the recess formed by opening 32, as shown in FIG. 2), it should be understood that frame portion 30 can be fabricated to have a plurality of compartments such that a single heat spreader can cover a plurality of individually framed devices (not shown). Alternatively, contemplated heat spreaders may be configured to cover a plurality of devices within a single framed compartment.

FIG. 8 shows integrated circuitry 100 comprising heat spreader 10 disposed over a single microelectronic device 104. Device 104 can be, for example, a flip-chip mounted on integrated circuitry board 102 utilizing, for example, a solder material 106, An interface material 110 can be provided between heat spreader 10 and board 102 in order to mount the heat spreader to the circuitry board. Material 110 can be, for example an interface adhesive or solder material.

A second interface material 108 can be provided between device 104 and heat spreader 20. Such material can be, for example, a thermal interface material such as thermal grease, phase change materials, thermal gels, indium, indium alloys, metallic thermal interface materials or other known interface materials. Typically, material 108 will cover only a portion of surface 23 which will overlie or interface a heat-generating device, as illustrated in FIG. 8. However in alternative aspects, material 108 can cover an entirety of surface 23, or portions of surface 23 which are not interfacing a heat generating device. It is also to be understood that the sizes of the heat spreader and surface 23 relative to heat-generating device shown in FIG. 8 are for illustrative purposes and alternative relative sizes are contemplated. In particular applications, the size of surface 23 relative to the heat-generating device will be much greater than depicted in FIG. 8.

In particular applications, surface 26 of heat spreader 10 can interface an ultimate heat sink (not shown). An appropriate heat sink can comprise any appropriate heat sink material end configuration known to those skilled in the art or yet to be developed.

Heat spreader configurations—both single and multi-piece—utilizing the materials disclosed herein can provide effective thermal management at lower cost and/or ease of fabrication relative to conventional heat spreaders, which use conventional heat spreader materials. It is important to reiterate that the materials and methods disclosed herein can be used to form single piece and multi-piece heat spreaders.

Methods of forming the heat spreader constructions are described above, including methods of incorporating such heat spreader constructions into integrated circuitry. Formation of heat spreader constructions can comprise machining or otherwise fabricating a base plate or base portion 20 and a frame potion 30 such as those depicted in FIG. 3. Appropriate materials for use during fabrication include those materials discussed above with respect to the base portion and frame portion The base portion and the frame portion can be formed of identical materials or can comprise materials of differing composition.

Base portion 20 can be joined to frame portion 10 by, for example, diffusion bonding such that interfacing surface 34 of frame 30 is in direct physical contact with perimeter region 24 of base portion 20 such as depicted in FIG. 2. Alternatively, the frame portion can be joined to the base portion utilizing methodology such as soldering or attaching utilizing application of an appropriate adhesive material.

Methodology utilized for forming a heat spreader construction can additionally include providing a coating material 24 over a portion or over an entirety of heat spreader surface 22 as shown in FIGS. 4-5, Coating 40 can comprise any of the coating materials discussed above. Coating 40 can be applied to all or a desired portion of surface 22 utilizing any appropriate coating methodology. In particular applications, for example where coating material 40 is utilized to assist attachment or joining the base portion with the frame portion, material 40 can be utilized to coat only perimeter region 24 or portions thereof and can accordingly be applied only to such per meter region. The base portion and frame portion can subsequently be joined utilizing any of the joining techniques discussed above.

Methods, as described, include incorporating heat spreader constructions of the invention into integrated circuitry. Such methodology can include providing an integrated circuitry board, a heat-generating device, such as for example, a flip-chip can be mounted on the circuitry board either prior to or at the time of mounting the heat spreader. A heat spreader such as any of the constructions described above is provided to be in thermal communication with the heat generating device. The providing can include mounting the heat spreader to the circuitry board. Such mounting can utilize an adhesive and/or a solder, for example. In particular applications, a thermal interface material can be provided between the heat-generating device and the heat-receiving surface. Such thermal interface material can be, for example, any of the thermal interface materials described above.

Thus, specific embodiments and applications of methods of manufacturing heat spreader compositions and integrated circuit have been disclosed. It should be apparent, however, to those skilled in the art that many more modifications besides those already described are possible without departing from the inventive concepts herein. The inventive subject matter, therefore, is not to be restricted except in the spirit of the disclosure and claims herein. Moreover, in interpreting the disclosure and claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

We claim:

1. A near net shape heat spreader component comprising at least one pressure-treated powder material.

2. The near net shape heat spreader component of claim 1, wherein the at least one pressure-treated powder material comprises copper, copper alloys, diamond, aluminum, aluminum alloys, carbon-carbon composite materials, copper composites, aluminum silicon carbide, copper-tungsten, copper-molybdenum copper, silicon carbide, copper silicon carbides, copper diamond powders, diamond composite materials, nanotubes/carbon fibers or combinations thereof.

3. The near net shape heat spreader component of claim 2, wherein the at least one pressure-treated powder material comprises copper, copper alloys, diamond, silicon carbide, copper silicon carbides, copper diamond powders, diamond composite materials or combinations thereof.

4. The near net shape heat spreader component of claim 3, wherein the at least one pressure-treated powder material comprises copper silicon carbides, copper diamond powders or combinations thereof.

5. The near net shape heat spreader component of claim 1, wherein the pressure-treating comprises hot isostatic pressing, hot pressing, press forming or a combination thereof.

6. The near net shape heat spreader component of claim 1 further comprising at least one additional thermally conductive material.

7. The near net shape heat spreader component of claim 6, wherein the at least one additional thermally conductive material is in the form of a textile, a web, a particle, a flake or a combination thereof.

8. The near net shape heat spreader component of claim 6, wherein the at least one additional thermally conductive material comprises carbon.

9. A heat spreader, comprising:
at least one near net shape heat spreader component, and
at least one additional part.

10. The heat spreader of claim 9, wherein the at least one near net heat spreader component comprises at least one pressure-treated powder material.

11. The heat spreader of claim 10, wherein the at least one pressure-treated powder material comprises copper, copper alloys, diamond, aluminum, aluminum alloys, carbon-carbon composite materials, copper composites, aluminum silicon carbide, copper-tungsten, copper-molybdenum copper, silicon carbide, copper silicon carbides, copper diamond powders, diamond composite materials or combinations thereof.

12. The heat spreader of claim 11, wherein the at least one pressure-treated powder material comprises copper, copper alloys, diamond, silicon carbide, copper silicon carbides, copper diamond powders, diamond composite materials or combinations thereof.

13. The heat spreader of claim 12, wherein the at least one pressure-treated powder material comprises copper silicon carbides, copper diamond powders or combinations thereof.

14. The heat spreader of claim 13, wherein the pressure-treating comprises hot isostatic pressing, hot pressing, press forming or a combination thereof.

15. The heat spreader of claim 9, wherein the near net shape heat spreader component and the at least one additional pad comprises the same material.

16. The heat spreader of claim 9, wherein the near net shape heat spreader component and the at least one additional pad comprises the same material.

17. The near net shape heat spreader of claim 1 or 9, wherein the spreader has a thermal conductivity of greater than about 350 W/mk.

18. The near net shape heat spreader of claim 1 or 9, wherein the spreader has a thermal conductivity of greater than about 400 W/mk.

19. The near net shape heat spreader of claim 1 or 9, wherein the spreader has a thermal conductivity of greater than about 500 W/mk.

20. The near net shape heat spreader of claim 1 or 9, wherein the spreader has a coefficient of thermal expansion of less than about 20 ppm/k.

21. The near net shape heat spreader of claim 1 or 9, wherein the spreader has a coefficient of thermal expansion of less than about 14 ppm/K.

22. The near net shape heat spreader of claim 1 or 9, wherein the spreader has a coefficient of thermal expansion of less than about 6 ppm/K.

23. A method of forming a heat spreader construction comprising:
forming a base portion comprising a pressure-treated powder material and having a first surface comprising a perimeter region surrounding a heat-receiving surface;
forming a frame portion comprising a second material; and
joining the base portion and the frame portion.

24. The method of claim 23, wherein the joining comprises attaching the frame portion and the perimeter region, the attaching comprising at least one of soldering, diffusion bonding and application of an adhesive material.
